(19) United States
(12) Patent Application Publication
(10) Pub. No.: US 2012/0309172 A1
(43) Pub. Date: Dec. 6, 2012

(54) Epitaxial Lift-Off and Wafer Reuse

(75) Inventors: Linda T. Romano, Sunnyvale, CA (US); David P. Bour, Cupertino, CA (US); Richard J. Brown, Los Gatos, CA (US); Andrew P. Edwards, San Jose, CA (US); Isik C. Kizilyalli, San Francisco, CA (US); Hui Nie, Cupertino, CA (US); Thomas R. Prunty, Santa Clara, CA (US)

(73) Assignee: EPOWERSOFT, INC., San Jose, CA (US)

(21) Appl. No.: 13/118,900

(22) Filed: May 31, 2011

(51) Int. Cl. H01L 21/20

(52) U.S. Cl. 438/478; 257/E21.09

(57) ABSTRACT

A method of reusing a III-nitride growth substrate according to embodiments of the invention includes epitaxially growing a III-nitride semiconductor structure on a III-nitride substrate. The III-nitride semiconductor structure includes a sacrificial layer and an additional layer grown over the sacrificial layer. The sacrificial layer is implanted with at least one implant species. The III-nitride substrate is separated from the additional layer at the implanted sacrificial layer. In some embodiments the III-nitride substrate is GaN and the sacrificial layer is GaN, an aluminum-containing III-nitride layer, or an indium-containing III-nitride layer. In some embodiments, the III-nitride substrate is separated from the additional layer by etching the implanted sacrificial layer.

### BACKGROUND

III-nitride materials, particularly binary, ternary, quaternary, and quinary alloys of gallium, boron, aluminum, indium, and nitrogen, have been used to produce semiconductor devices, particularly light emitting diodes and laser diodes. III-nitride materials may also have advantages for power electronics, particularly in applications requiring high voltage, high temperature operation, or high frequency operation.

III-nitride devices are often fabricated on a substrate by an epitaxial growth technique such as metal organic chemical vapor deposition. N-type layers are typically doped with Si and p-type layers are typically doped with Mg.

The substrate is typically a non-III-nitride substrate such as sapphire or silicon carbide. Sapphire is often used as a substrate because of its wide availability and low cost. III-nitride material grown on sapphire includes defects such as dislocations because of the difference between the lattice constants and the coefficients of thermal expansion of sapphire and III-nitride material.

### SUMMARY

A method of reusing a III-nitride growth substrate according to embodiments of the invention includes epitaxially growing a III-nitride semiconductor structure on a III-nitride substrate. The III-nitride semiconductor structure includes a sacrificial layer and an additional layer grown over the sacrificial layer. The sacrificial layer is implanted with at least one implant species. The substrate is separated from the additional layer at the implanted sacrificial layer. In some embodiments the substrate is GaN and the sacrificial layer is GaN, an aluminum-containing III-nitride layer, or an indium-containing III-nitride layer. In some embodiments, the substrate is separated from the additional layer by etching the implanted sacrificial layer.

### BRIEF DESCRIPTION OF THE DRAWINGS

FIG. 1 illustrates a sacrificial layer and an additional layer grown on a substrate.

FIG. 2 illustrates implanting the sacrificial layer of FIG. 1.

FIG. 3 illustrates attaching the additional layer to a handle and removing the substrate.

FIG. 4 illustrates implantation of the sacrificial layer.

FIG. 5 illustrates a spacer layer, sacrificial layer, and additional layer grown on a substrate.

FIG. 6 illustrates a super-lattice sacrificial layer.

FIG. 7 illustrates implantation of a sacrificial layer that is the same composition as the additional layer.

FIG. 8 illustrates the structure of FIG. 7 after implantation.

### DETAILED DESCRIPTION

GaN or other III-nitride substrates are preferred to non-III-nitride substrates because III-nitride device layers can be grown on III-nitride substrates with fewer defects than III-nitride device layers grown on sapphire, silicon carbide, and other non-III-nitride substrates. GaN substrates, however, and not widely available and are expensive, particularly compared to substrates such as sapphire and silicon.

In accordance with embodiments of the invention, techniques are described to reuse a GaN, other III-nitride, or other growth substrate for a III-nitride device. The substrate is removed in a wafer-scale process. Though in the embodiments below, the reused substrate is a GaN substrate, the techniques described herein can be used with any suitable growth substrate.

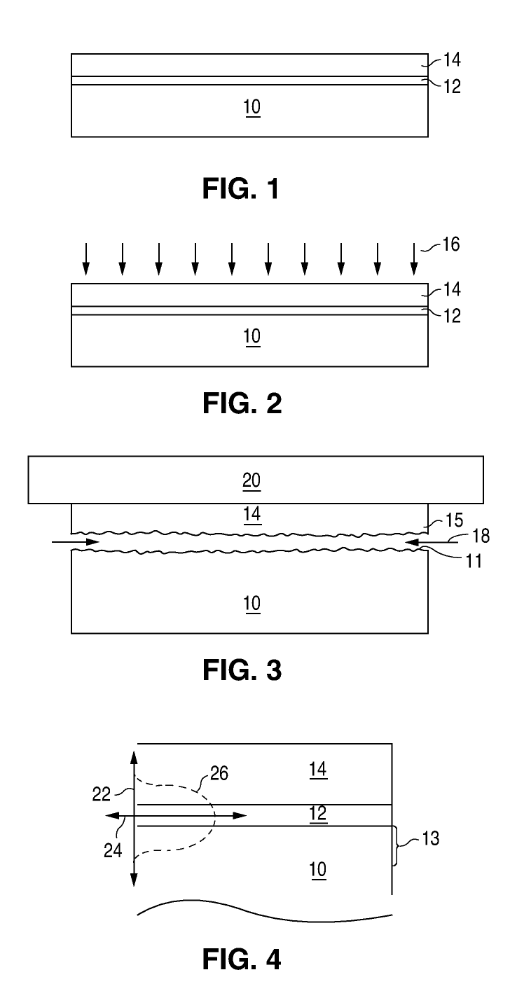

FIGS. 1-3 illustrate a first embodiment of removing a growth substrate such that the substrate can be reused.

In FIG. 1, a sacrificial layer 12 is grown over GaN substrate 10, followed by an additional III-nitride layer 14. In some embodiments, the composition and thickness of sacrificial layer 12 are selected such that additional III-nitride layer 14 can be grown on sacrificial layer 12 with a sufficiently low concentration of defects. In one example, sacrificial layer 12 is AlN and substrate 10 is GaN. In order to grow high quality III-nitride material over sacrificial layer 12, sacrificial layer 12 is grown such that it remains epitaxial to substrate 10, meaning that it replicates the crystal structure of substrate 10. Since AlN is in tension when grown on GaN, sacrificial layer 12 must be grown thin enough that it remains epitaxial to GaN substrate 10, rather than cracking to relieve the strain. An AlN sacrificial layer 12 is grown to a thickness between 5 nm and 500 nm in some embodiments, between 10 nm and 200 nm in some embodiments, and between 50 nm and 150 nm in some embodiments. In order to remain epitaxial to substrate 10, an AlN sacrificial layer 12 may be grown at a temperature of at least 1000° C. in some embodiments, a least 1100° C. in some embodiments, and at least 1200° C. in some embodiments. In another example, sacrificial layer 12 is ZnO. In another example, sacrificial layer 12 is an aluminum-containing III-nitride layer such as AlGaN, for example with an AlN composition greater than zero and no more than 10%, or an indium-containing III-nitride layer such as InN, InGaN, or AlGaInN.

Additional layer 14 is grown over sacrificial layer 12. Additional layer 14 may be a single GaN layer, a single III-nitride layer, or a multi-layer stack. In some embodiments, additional layer 14 includes the entire device structure, such that no further epitaxial growth is required after removing the substrate as illustrated in FIG. 3. A device structure may include multiple layers of different composition and/or dopant concentration. A device structure may include both n- and p-type layers. In some embodiments, additional layer 14 does not include the entire device structure. In those embodiments, after the implant described below and before or after removing substrate 10, a structure including additional layer 14 is returned to a growth reactor and all or the remaining portion of the device structure is grown on additional layer 14. Additional layer 14 has a thickness between 500 nm and 100 μm in some embodiments, between 1 μm and 10 μm in some embodiments, between 1 μm and 3 μm in some embodiments, and between 10 nm and 100 nm in some embodiments. Additional layer 14 may be thick, for example on the order of microns or tens of microns, when additional layer 14 includes all or part of a device structure. Additional layer 14 may be thin, for example on the order of tens or hundreds of nanometers, when the device structure is grown after the implant described below. The thickness of both sacrificial layer 12 and additional layer 14 are selected to match the implant conditions required to make sacrificial layer 12 amorphous.

In FIG. 2, after growth of additional layer 14, sacrificial layer 12 is made at least partially amorphous by an implant 16. The implant species, implant energy, and implant dose are selected such that the implant species passes through the additional layer 14 to sacrificial layer 12. Implant 16 breaks bonds in sacrificial layer 12, destroying the crystalline structure of sacrificial layer 12 and making sacrificial layer 12 at least partially amorphous and brittle. In some embodiments, in addition to or instead of making sacrificial layer 12 at least partially amorphous, implant 16 creates voids in sacrificial layer 12. Processing steps after implant, such as elevating the temperature of the structure, for example to grow an additional semiconductor layer, may create or increase the size of the voids. The size of the voids may be, for example, no more than the thickness of additional layer 14 grown over sacrificial layer 12. The implant alone or the implant combined with further processing such as heating creates a zone of weakness at sacrificial layer 12, for example due to the presence of at least partially amorphous material, etchable material such as an oxide, and/or voids. The zone of weakness at sacrificial layer 12 may be mechanically separated from the growth substrate and/or selectively etched to release the growth substrate, as described below.

Examples of suitable implant species include H, He, C, N, O, Mg, Al, Si, Ar, Hf, and other metals. Lighter implant species such as H and He are appropriate for a deep implant, for example when additional layer 14 is thick. In some embodiments, more than one implant species is used. For example, Si and O can be coimplanted. Specifically, Si can be implanted in a first implant and O can be implanted in a second implant. The implant conditions for the first and second implants are selected such that the Si and O implant regions overlap. In some embodiments, the implant species may be selected based on the dopant type of a region near the implanted region. For example, if the additional layer adjacent to the sacrificial region is n-type, the implant species may be an n-type dopant such as Si. If the additional layer adjacent to the sacrificial region is p-type, the implant species may be a p-type dopant such as Mg. The implant energy is between 10 keV and 3000 keV or more in some embodiments, between 100 and 500 keV in some embodiments, between 300 keV and 700 keV in some embodiments, and between 400 keV and 600 keV in some embodiments. The implant dose may be between 1×10¹⁴ cm⁻² and 3×10¹⁸ cm⁻² in some embodiments and between 1×10¹⁷ cm⁻² and 3×10¹⁸ cm⁻² in some embodiments.

Table 1 illustrates the implant depth and straggle for implants of several species at an implant energy of 100 keV. The straggle is the thickness of material both above and below the implant depth that is damaged by the implant. For example, in the case of hydrogen as shown in Table 1, the implant depth is 5656 Å. Above that depth, 1241 Å of material are damaged by the implant, and below that depth, 1241 Å material are damaged by the implant, such that the total thickness of the implant is 2481 Å of material centered at a depth of 5656 Å. In some embodiments, for a given implant species and energy, the sacrificial layer 12 is grown to a thickness of twice the straggle, and the thickness of additional layer 14 is selected such that the center of the sacrificial layer 12 is at the implant depth.

TABLE 1

| Implant Species | Depth (Å) | Straggle (Å) |
|---|---|---|
| Hydrogen | 5656 | 1241 |
| Helium | 4131 | 1323 |
| Carbon | 1669 | 654 |
| Nitrogen | 1429 | 559 |
| Oxygen | 1327 | 530 |
| Magnesium | 991 | 400 |
| Aluminum | 884 | 340 |
| Silicon | 750 | 278 |
| Argon | 568 | 191 |
| Hafnium | 217 | 54 |

Table 2 illustrates the implant depth and straggle for implants of several species at an implant energy of 400 keV.

TABLE 2

| Implant Species | Depth (Å) | Straggle (Å) |
|---|---|---|
| Hydrogen | 25200 | 3045 |
| Helium | 11300 | 2150 |
| Carbon | 5711 | 1528 |
| Nitrogen | 5178 | 1428 |
| Oxygen | 4953 | 1437 |
| Magnesium | 4262 | 1405 |
| Aluminum | 3739 | 1186 |
| Silicon | 3155 | 941 |
| Argon | 2354 | 655 |
| Hafnium | 616 | 133 |

Table 3 illustrates the implant depth and straggle for implants of several species at an implant energy of 1000 keV.

TABLE 3

| Implant Species | Depth (Å) | Straggle (Å) |
|---|---|---|
| Hydrogen | 87000 | 7910 |
| Helium | 22400 | 2796 |
| Carbon | 11300 | 2222 |
| Nitrogen | 10300 | 2140 |
| Oxygen | 10200 | 2256 |
| Magnesium | 9267 | 2471 |
| Aluminum | 8481 | 2197 |
| Silicon | 7233 | 1797 |
| Argon | 5848 | 1402 |
| Hafnium | 1377 | 265 |

In some embodiments, one or more semiconductor layers are grown over additional layer 14 after implant. The semiconductor layers grown after implant may be grown by any suitable technique. In some embodiments, the layers grown after implant include all or part of a device structure. In some embodiments, a thick layer is grown by a fast growth technique such as vapor phase epitaxy, then a thinner, high quality layer which may form a layer of a device is grown over the thick layer by a slower growth method such as chemical vapor deposition. The presence of the thick layer may support the thinner layer to prevent or reduce damage during removal of the growth substrate, described below.

In FIG. 3, the structure is attached to a handle 20 via the top surface of additional layer 14 or other semiconductor layers grown over additional layer 14 after implanting, then substrate 10 is removed. Handle 20 may be, for example, a mount on which the final devices are to be attached such as a silicon mount, a metal mount, or a printed circuit board, or a conventional wafer handling material such as a plastic or polyimide film.

Substrate 10 is often removed by an etch 18 that selectively etches amorphous sacrificial layer 12 of FIG. 2 without damaging other semiconductor material such as additional layer 14 or substrate 10. Any suitable etchant may be used. Amorphous AlN, AlGaN, indium-containing III-nitride layers, or ZnO can be etched by, for example, HF, which etches the amorphous material and does not etch GaN. Coimplanted species such as Mg and O, Hf and O, other metals and O, Si and O, Si and N, Zn and O, and Si, O, and N can be etched by, for example, HF. The etchant may penetrate the structure from the sides, as illustrated in FIG. 3. In some embodiments, substrate 10 is removed by mechanical means, such as separating substrate 10 from additional layer 14 at the zone of weakness formed by implant 16 by inserting a blade or by pulling substrate 10 and additional layer 14 apart. In some embodiments, substrate 10 is removed by etching combined with a mechanical technique such as lift-off or any other suitable mechanical technique.

Separating the substrate 10 from the additional layer 14 causes a rough surface 11 on the top of the substrate 10 and a rough surface 15 on the bottom of additional layer 14. The top surface 11 of substrate 10 may be treated, for example by polishing, heating, and/or cleaning with solvent to repair, reduce, or remove the roughness, before substrate 10 is reused. The bottom surface 15 of additional layer 14 may be similarly treated before further processing of additional layer 14.

Implant 16 is illustrated in FIG. 4. Axis 22 represents the position on the semiconductor structure, which includes substrate 10, sacrificial layer 12, and additional layer 14. Axis 24 represents the concentration of implanted species. Curve 26 illustrates the implant. The conditions are selected such that the peak of curve 26, which represents the highest concentration of implant species, is located within sacrificial layer 12. In some embodiments, for example in the case of a strained sacrificial layer 12, such as an aluminum-containing or indium-containing sacrificial layer 12, which must be thin in order to remain epitaxial to substrate 10 and additional layer 14, the implanted region is thicker than sacrificial layer 12, as illustrated by curve 26. In the structure illustrated by FIG. 4, a portion 13 of substrate 10 is implanted. Implanted portion 13 is damaged by implant 16 and is therefore removed before substrate 10 can be reused.

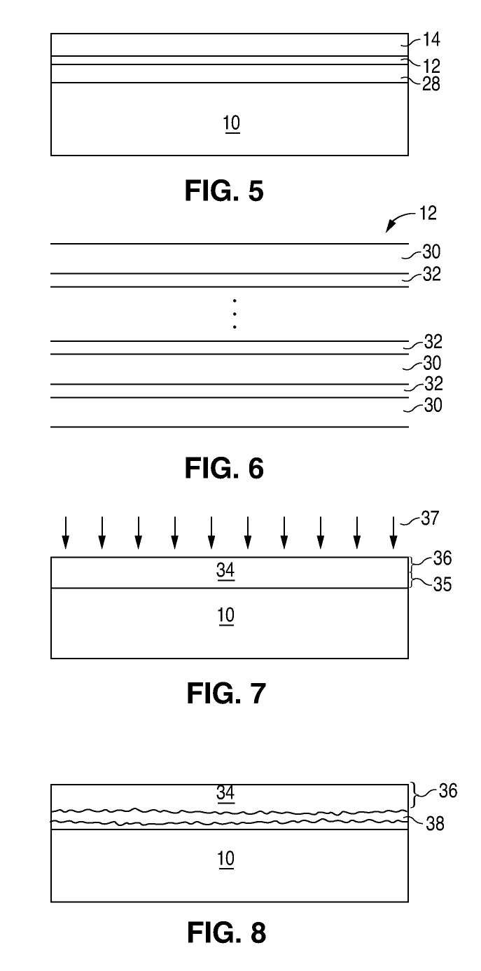

In order to protect substrate 10 from damage from implant 16, in some embodiments a spacer layer 28 is grown first over substrate 10, as illustrated in FIG. 5. The thickness of spacer layer 28 is selected to space the implanted region apart from substrate 10, so none of substrate 10 is damaged by the implant. The composition and thickness of spacer layer 28 are also selected such that spacer layer 28 remains epitaxial to substrate 10 and such that sacrificial layer 12 can be grown epitaxially and additional layer 14 can be grown epitaxially and with sufficiently high quality over sacrificial layer 12 and spacer layer 28. In some embodiments, spacer layer 28 is GaN, AlGaN, for example with an AlN composition greater than zero and no more than 10%, or a III-nitride material containing indium, such as InN, InGaN, or AlGaInN. Spacer layer 28 may have a thickness between 1 μm and 10 μm in some embodiments, between 2 μm and 8 μm in some embodiments, and between 4 μm and 6 μm in some embodiments. The thickness of spacer layer 28 may be determined, for example, by the thickness of sacrificial layer 12 and the implant conditions and species.

As described above, in order for a strained sacrificial layer 12 to remain epitaxial to substrate 10, sacrificial layer 12 must be thinner than the threshold for cracking, which may be thinner than the total thickness of implanted material. Examples of strained sacrificial layers include AlN, AlGaN, InN, InGaN, and some AlGaInN layers layers. In some embodiments, in order to grow a thicker sacrificial layer 12, sacrificial layer 12 is a compositional super-lattice, as illustrated in FIG. 5. The super-lattice includes multiple pairs of alternating layers 30 and 32 of different composition. In some embodiments, layers 30 are more highly strained than layers 32, which may be strained or unstrained. In one embodiment, AlN layers 30 alternate with GaN or AlGaN layers 32. In some embodiments, indium-containing layers 30 alternate with GaN or indium-containing layers with a smaller composition of InN 32. All layers in the super-lattice must remain epitaxial to substrate 10. All of the first type of layer 30 in the super-lattice may have the same composition and thickness, though they need not. Similarly, all of the second type of layer 32 in the super-lattice may have the same composition and thickness, though they need not.

In some embodiments, more highly strained layers 30 are thicker than less highly strained layers 32. Layers 30 may be one to ten times thicker than layers 32 in some embodiments, one to five times thicker in some embodiments, and one to two times thicker in some embodiments. In some embodiments, less highly strained layers 32 are the same thickness as or thicker than more highly strained layers 30. Each of layers 30 and 32 may be no more than 20 nm thick in some embodiments and no more than 10 nm thick in some embodiments. Layers 30 may be between 1 and 10 nm thick in some embodiments. Layers 32 may be between 1 and 5 nm thick in some embodiments. The super-lattice may include between 2 and 25 pairs of layers 30 and 32 in some embodiments. The total thickness of the super-lattice may be between 0.1 and 5 microns in some embodiments. An additional layer, as described above, is grown over the super-lattice, then all or a portion of the super-lattice is implanted with one or more implant species, as described above. After implanting, optional additional semiconductor layers may be grown. The substrate is then separated from the additional layer, as described above.

In some embodiments, the sacrificial layer is the same composition as substrate 10, usually GaN. FIG. 7 illustrates such a structure. A GaN layer 34 is grown over substrate 10. The first portion 35 serves as the sacrificial layer. The second portion 36 may be a single GaN layer, a single layer of another composition, or a device structure including multiple layers of different composition and/or dopant concentration as described above in reference to FIG. 1. Sacrificial portion 35 is implanted 37 with an implant species that makes sacrificial portion brittle and amorphous such as, for example, any of the implant species described above. For example, sacrificial portion 35 may be coimplanted with Si and O. When heated, for example during a separate anneal or during a later growth step, the implanted Si and O form a region 38 of oxides of silicon such as SiO₂, as illustrated in FIG. 8. One or more additional optional semiconductor layers may be grown after implanting. The semiconductor structure is then connected to a handle, as described above in reference to FIG. 3, then substrate 10 is separated from additional layer 34, for example by etching implanted region 38 with HF, or with any other suitable etchant, by a mechanical separation technique, or by a combination of etching and a mechanical technique such as lift-off or any other suitable mechanical technique.

As described above in reference to FIG. 4, after separation, the top surface of substrate 10 and the bottom surface of additional layer 34 may be damaged. The damaged area may be removed or repaired before reusing substrate 10 or before further processing or growth on additional layer 34. For example, the damaged area may be polished using the same polishing technique used to prepare an undamaged substrate for growth.

Any suitable device structure may be grown within or over additional layers 14 and 34 illustrated in FIGS. 1, 2, 3, 4, 5, 7, and 8, including but not limited to high electron mobility transistors, diodes, field effect transistors, light emitting diodes, lasers, and other electronic and optoelectronic devices. In any of the embodiments described above, all or part of the device structure may be grown before implanting, after implanting but before the substrate is removed, or after the substrate is removed. In some embodiments, all or part of the additional layers 14 and 34 are unstrained or have very little strain. For example, a GaN additional layer or device structure grown on a GaN substrate will generally be unstrained. In some embodiments, all or part of the additional layers 14 and 34 have very few or no defects. For example, additional layers 14 and 34 may have a defect density no greater than 10⁶ cm⁻² in some embodiments, no greater than 10⁵ cm⁻² in some embodiments, and no greater than 10⁴ cm⁻² in some embodiments.

Having described the invention in detail, those skilled in the art will appreciate that, given the present disclosure, modifications may be made to the invention without departing from the spirit of the inventive concept described herein. Aspects of some embodiments may be omitted. Aspects and features of different embodiments may be combined. Therefore, it is not intended that the scope of the invention be limited to the specific embodiments illustrated and described.

1. A method comprising:
epitaxially growing a III-nitride semiconductor structure on a III-nitride substrate, the III-nitride semiconductor structure comprising:
a sacrificial layer; and
an additional layer grown over the sacrificial layer;
implanting the sacrificial layer with at least one implant species;
thereafter, growing one or more semiconductor layers over the additional layer; and
separating the III-nitride substrate from the additional layer at the implanted sacrificial layer.

2. The method of claim 1 further comprising after separating the III-nitride substrate from the additional layer, polishing the III-nitride substrate and growing a III-nitride layer on the III-nitride substrate.

3. The method of claim 1 wherein the III-nitride substrate is GaN.

4. The method of claim 1 wherein the additional layer is the same material as the III-nitride substrate.

5. The method of claim 1 wherein the sacrificial layer comprises aluminum.

6. The method of claim 1 wherein the sacrificial layer comprises at least one of GaN, AlN, AlGaN, or an indium-containing III-nitride layer.

7. The method of claim 1 wherein the substrate is GaN, the sacrificial layer is AlN, and the additional layer is GaN.

8. The method of claim 1 wherein the substrate is GaN, the sacrificial layer is GaN, and the additional layer is GaN.

9. The method of claim 1 wherein the sacrificial layer is a compositional super-lattice comprising alternating first and second layers, the first layers having a different composition than the second layers.

10. The method of claim 9 wherein the first layers comprise aluminum and the second layers are GaN.

11. The method of claim 9 wherein the first layers comprise indium and the second layers are GaN.

12. The method of claim 9 wherein the compositional super-lattice comprises at least two pairs of alternating first and second layers.

13. The method of claim 1 wherein the implant species comprises at least one of He or H.

14. The method of claim 1 wherein the sacrificial layer is implanted with at least two implant species, wherein one of the implant species is O.

15. The method of claim 1 wherein separating comprises etching.

16. The method of claim 14 wherein etching comprises etching with HF.

17. The method of claim 1 wherein separating comprises mechanically separating.

18. The method of claim 1 wherein epitaxially growing a III-nitride semiconductor structure on a III-nitride substrate further comprises epitaxially growing a spacer layer disposed between the III-nitride substrate and the sacrificial layer.

19. The method of claim 18 wherein the spacer layer is GaN.

20. The method of claim 1 wherein the additional layer is a first additional layer, the method further comprising after implanting the sacrificial layer and before separating the III-nitride substrate from the additional layer, growing a second additional III-nitride layer on the first additional layer.

21. The method of claim 1 wherein implanting the sacrificial layer makes the sacrificial layer at least partially amorphous.

22. The method of claim 1 wherein implanting the sacrificial layer creates at least one void in the sacrificial layer.
